(19) United States
(12) Patent Application Publication
(10) Pub. No.: US 2013/0239881 A1
(43) Pub. Date: Sep. 19, 2013

(54) METHOD AND DEVICE FOR MANUFACTURING SILICON CARBIDE SINGLE-CRYSTAL

(71) Applicant: SUMITOMO ELECTRIC INDUSTRIES, LTD., Osaka (JP)

(72) Inventors: Hiroki INOUE, Itami-shi (JP); Makoto SASAKI, Itami-shi (JP); Shin HARADA, Osaka-shi (JP); Shinsuke FUJIWARA, Itami-shi (JP)

(73) Assignee: SUMITOMO ELECTRIC INDUSTRIES, LTD., Osaka (JP)

(21) Appl. No.: 13/753,941

(22) Filed: Jan. 30, 2013

Related U.S. Application Data
(60) Provisional application No. 61/611,108, filed on Mar. 15, 2012.

(30) Foreign Application Priority Data
Mar. 15, 2012 (JP) 2012-058194

(51) Int. Cl. C30B 23/02

(52) U.S. Cl. CPC C30B 23/025
USPC 117/106; 118/726

(57) ABSTRACT

A method for manufacturing a silicon carbide single-crystal having a diameter of more than 100 mm and a maximum height of 20 mm or more using a sublimation method includes the following steps. That is, there are prepared a seed substrate made of silicon carbide and a silicon carbide source material. By sublimating the silicon carbide source material, the silicon carbide single-crystal is grown on a growth surface of the seed substrate. In the step of growing the silicon carbide single-crystal, a first carbon member provided at a position facing a side wall of the seed substrate is etched at a rate of 0.1 mm/hour or less. By suppressing a change in growth condition for the silicon carbide single-crystal in the crucible, there can be provided a method for manufacturing a silicon carbide single-crystal so as to stably grow the silicon carbide single-crystal.

### BACKGROUND OF THE INVENTION

1. Field of the Invention

The present invention relates to method and device for manufacturing a silicon carbide single-crystal, more particularly, method and device for manufacturing a silicon carbide single-crystal so as to grow the silicon carbide single-crystal on a growth surface of a seed substrate.

2. Description of the Background Art

In recent years, a silicon carbide substrate has begun to be used in manufacturing semiconductor devices. Silicon carbide has a band gap larger than that of silicon. Hence, a semiconductor device employing a silicon carbide substrate advantageously has a high breakdown voltage, low on-resistance, and properties less likely to decrease in a high temperature environment.

As a method for manufacturing the above-described silicon carbide substrate, for example, Japanese Patent Laying-Open No. 5-58774 describes a method for manufacturing a silicon carbide single-crystal substrate using a sublimation method. According to this method, a silicon carbide single-crystal is grown in the following manner. That is, a silicon carbide source material disposed in a crucible made of carbon is sublimated at a high temperature, and resulting sublimation gas is recrystallized on a seed substrate disposed opposite to the silicon carbide source material.

### SUMMARY OF THE INVENTION

However, if a silicon carbide single-crystal is grown using the method described in Japanese Patent Laying-Open No. 5-58774, a side surface portion of the crucible will be etched. When the side surface portion of the crucible is etched, a growth condition for a silicon carbide single-crystal is changed in the crucible.

The present invention has been made to solve the foregoing problem, and has its object to provide method and device for manufacturing a silicon carbide single-crystal so as to stably grow the silicon carbide single-crystal by suppressing a change in growth condition for the silicon carbide single-crystal in a crucible.

The following describes one conceivable reason why the side surface portion of the crucible is etched. That is, when the silicon carbide source material is sublimated, silicon carbide gas, silicon gas, and carbon gas are generated around the seed substrate in the crucible. When the silicon carbide gas starts to be recrystallized on the seed substrate, an amount of the silicon gas becomes relatively large and an amount of the carbon gas becomes relatively small around the seed substrate. Accordingly, the side surface portion of the crucible made of carbon around the seed substrate is etched to maintain an equilibrium state of the atmospheric gas around the seed substrate.

As a result of diligent study, the inventors have found that the side surface portion of the crucible is etched in a more noticeable manner as the silicon carbide single-crystal grown on the seed substrate is adapted to have a larger diameter.

In view of this, a method for manufacturing a silicon carbide single-crystal in the present invention is a method for manufacturing a silicon carbide single-crystal having a diameter of more than 100 mm and a maximum height of 20 mm or more using a sublimation method, and includes the following steps. A seed substrate made of silicon carbide, and a silicon carbide source material are prepared. The silicon carbide single-crystal is grown on a growth surface of the seed substrate by sublimating the silicon carbide source material. A first carbon member provided at a position facing a side wall of the seed substrate is etched at a rate of 0.1 mm/hour or less in the step of growing the silicon carbide single-crystal.

According to the method for manufacturing the silicon carbide single-crystal in the present invention, the first carbon member provided at the position facing the side wall of the seed substrate is etched at a rate of 0.1 mm/hour or less. Because the carbon member is etched at such a low rate, a change in growth condition for the silicon carbide single-crystal is small in the crucible. Accordingly, the silicon carbide single-crystal can be grown stably.

Preferably in the method for manufacturing the silicon carbide single-crystal, in the step of growing the silicon carbide single-crystal, the first carbon member is etched at a rate of 0.05 mm/hour or less. Accordingly, the silicon carbide single-crystal can be grown more stably.

Preferably in the method for manufacturing the silicon carbide single-crystal, the silicon carbide single-crystal has a maximum height of 50 mm or more. In this way, a silicon carbide single-crystal having a maximum height of 50 mm or more can be obtained.

Preferably, the method for manufacturing the silicon carbide single-crystal further includes the step of disposing a second carbon member between the seed substrate and the silicon carbide source material before the step of growing the silicon carbide single-crystal. In the step of growing the silicon carbide single-crystal, the first carbon member is etched at a rate slower than a rate at which the second carbon member is etched.

According to the method for manufacturing the silicon carbide single-crystal, the first carbon member is etched at the rate slower than the rate at which the second carbon member is etched. Thus, the etching of the side surface portion of the crucible, i.e., the first carbon member can be suppressed.

Preferably in the method for manufacturing the silicon carbide single-crystal, a distance from the growth surface of the seed substrate to the second carbon member is shorter than a distance from a center of the growth surface of the seed substrate to the first carbon member. Accordingly, the etching of the second carbon member precedes the etching of the first carbon member, whereby the etching of the side surface portion of the crucible, i.e., the first carbon member can be suppressed.

Preferably in the method for manufacturing the silicon carbide single-crystal, the second carbon member is provided with a flow path for flowing silicon carbide gas, which is sublimated from the silicon carbide source material, from a side of the silicon carbide source material to a side of the seed substrate. The flow path is provided at a position facing the growth surface of the seed substrate. In this way, the sublimated silicon carbide gas can be brought to the seed substrate side via the flow path.

A device for manufacturing a silicon carbide single-crystal in the present invention is a device for manufacturing a silicon carbide single-crystal using a seed substrate having a growth surface on which the silicon carbide single-crystal is to be grown, and includes a crucible and a second carbon member. The crucible is for containing a silicon carbide source material, and has a side surface portion formed of a first carbon member disposed at a position facing a side wall of the seed substrate. The second carbon member is disposed between the seed substrate and the silicon carbide source material. The second carbon member forms a flow path for flowing silicon carbide gas, which is sublimated from the silicon carbide source material, from a side of the silicon carbide source material to a side of the seed substrate. The flow path is provided at a position facing the growth surface of the seed substrate. A distance from the growth surface of the seed substrate to the second carbon member is shorter than a distance from a center of the growth surface of the seed substrate to the first carbon member disposed at the position facing the side wall of the seed substrate.

According to the device for manufacturing the silicon carbide single-crystal in the present invention, the distance from the growth surface of the seed substrate to the second carbon member is shorter than the distance from the center of the growth surface of the seed substrate to the first carbon member disposed at the position facing the side wall of the seed substrate. Accordingly, the etching of the second carbon member precedes the etching of the first carbon member, whereby the etching of the side surface portion of the crucible, i.e., the first carbon member can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view schematically showing a configuration of a manufacturing device of a silicon carbide single-crystal in a first embodiment of the present invention.

FIG. 2 is a schematic plan view schematically showing a configuration of a second carbon member of the manufacturing device of the silicon carbide single-crystal in the first embodiment of the present invention.

FIG. 3 is a schematic cross sectional view schematically showing a configuration of a manufacturing device of a silicon carbide single-crystal in a second embodiment of the present invention.

FIG. 4 is a flowchart schematically showing a method for manufacturing a silicon carbide single-crystal in the first embodiment of the present invention.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

Regarding crystallographic indications in the present specification, an individual orientation is represented by [ ], a group orientation is represented by < >, and an individual plane is represented by ( ), and a group plane is represented by { }. In addition, a negative index is supposed to be crystallographically indicated by putting “−” (bar) above a numeral, but is indicated by putting the negative sign before the numeral in the present specification. For description of an angle, a system in which an omnidirectional angle is 360° is employed.

### First Embodiment

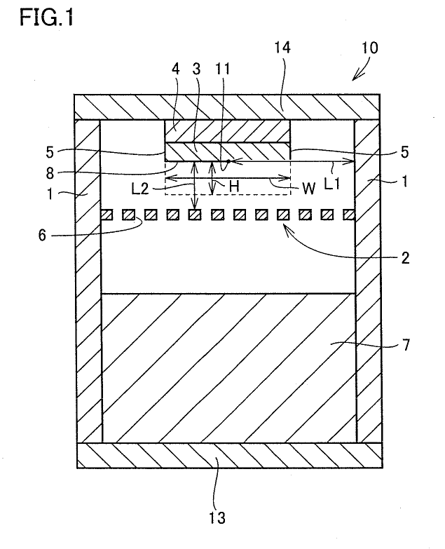

Referring to FIG. 1, a manufacturing device 10 of a silicon carbide single-crystal in the present embodiment is a manufacturing device 10 for growing a silicon carbide single-crystal using a sublimation method, and mainly includes a crucible 14, a seed substrate holding unit 4, a seed substrate 3, and a second carbon member 2. In crucible 14, a silicon carbide source material 7 is contained. Crucible 14 is formed of a carbon member. An exemplary carbon member is graphite. Crucible 14 includes side surface portions each formed of a first carbon member 1, and a bottom portion 13.

In crucible 14, seed substrate holding unit 4 is provided at a side opposite to silicon carbide source material 7 contained therein. Seed substrate 3 is held by seed substrate holding unit 4. Seed substrate 3 includes: a growth surface 8 on which a silicon carbide single-crystal is to be grown thereon; and side walls 5 surrounding growth surface 8. At respective positions facing side walls 5 of seed substrate 3, first carbon members 1 forming the side surface portions of crucible 14 are disposed.

Second carbon member 2, which is formed of a carbon member, is disposed between seed substrate 3 and silicon carbide source material 7. An exemplary carbon member is graphite. Second carbon member 2 is in the form of a mesh, for example.

Further, second carbon member 2 forms flow paths 6 for flowing silicon carbide gas, which is sublimated from silicon carbide source material 7, from the silicon carbide source material 7 side to the seed substrate 3 side. Flow paths 6 are provided at positions facing growth surface 8 of seed substrate 3. A distance L2 from growth surface 8 of seed substrate 3 to second carbon member 2 is shorter than a distance L1 from center 11 of growth surface 8 of seed substrate 3 to first carbon member 1 disposed at the position facing each side wall 5 of seed substrate 3. In the present embodiment, distance L2 from growth surface 8 of seed substrate 3 to second carbon member 2 is 50 mm.

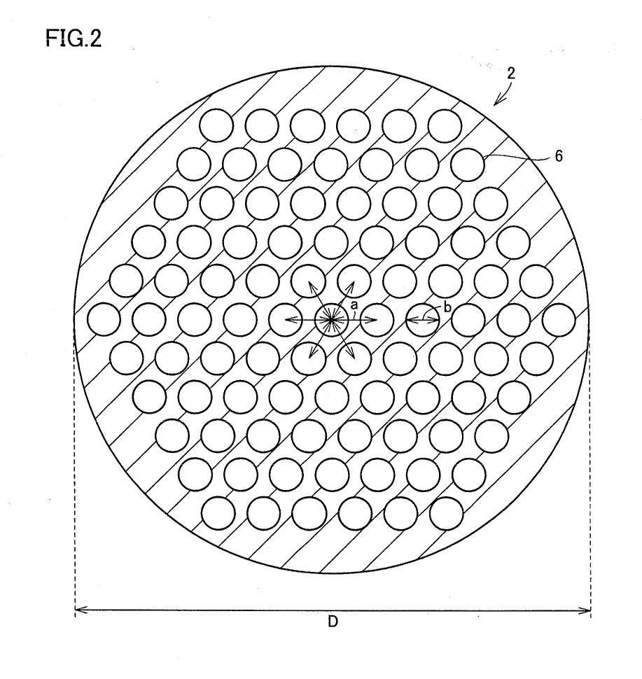

Referring to FIG. 2, the following describes a configuration of second carbon member 2. FIG. 2 is a plan view of second carbon member 2 of FIG. 1 when viewed from seed substrate 3 in a direction of silicon carbide source material 7.

As shown in FIG. 2, second carbon member 2 is provided with flow paths 6 for flowing the sublimated silicon carbide gas from the silicon carbide source material 7 side to the seed substrate 3 side. Each of flow paths 6 has a circular shape, for example. In the figure, the plurality of flow paths 6 are provided at a constant interval in the upward/downward direction, the leftward/rightward direction, and the oblique direction. In the present embodiment, each of flow paths 6 has a diameter b of 11 mm, and has a pitch a of 15 mm. Further, second carbon member 2 has a diameter D of 170 mm. The number of flow paths 6 formed in second carbon member 2 is 91.

It should be noted that the shape, size, number, arrangement of flow paths 6 are not particularly limited as long as flow paths 6 are provided at the positions facing growth surface 8 of seed substrate 3. For example, each of flow paths 6 may have a shape of polygon such as a quadrangle or a hexagon, or may have a shape of ellipse. Further, one or a plurality of flow paths 6 may be provided. Further, flow paths 6 may be arranged in a periodic manner or a symmetrical manner, or may be arranged in a random manner. The arrangement of flow paths 6 may be of three-fold symmetry or six-fold symmetry, for example.

The following describes a method for manufacturing a silicon carbide single-crystal in the present embodiment.

Referring to FIG. 4, the method for manufacturing the silicon carbide single-crystal in the present embodiment is a method for manufacturing a silicon carbide single-crystal having a diameter of more than 100 mm and a maximum height of 20 mm or more, using a sublimation method. The method mainly includes a seed substrate preparing step (S10) and a silicon carbide single-crystal growing step (S20).

First, in seed substrate preparing step (S10), seed substrate 3 made of silicon carbide is prepared. Seed substrate 3 is formed of a silicon carbide single-crystal. Growth surface 8 of seed substrate 3 corresponds to a {0001} plane, for example. Growth surface 8 may correspond to a plane inclined relative to the {0001} plane by an off angle of approximately 8° or smaller, for example. Further, in this step, silicon carbide source material 7 is prepared.

Next, in silicon carbide single-crystal growing step (S20), a silicon carbide single-crystal is grown on growth surface 8 of seed substrate 3. The silicon carbide single-crystal is grown using the sublimation method. By sublimating silicon carbide source material 7 contained in crucible 14, resulting sublimation gas is recrystallized on growth surface 8 of seed substrate 3, whereby a silicon carbide single-crystal grows on growth surface 8. It should be noted that in the step of growing the silicon carbide single-crystal in the present embodiment, first carbon member 1 provided at the position facing side wall 5 of seed substrate 3 is etched at a rate of 0.1 mm/hour or less. First carbon member 1 is, for example, the side surface portion of crucible 14. Preferably, in the step of growing the silicon carbide single-crystal, first carbon member 1 is etched at a rate of 0.05 mm/hour or less. Further, in the step of growing the silicon carbide single-crystal in the present embodiment, the silicon carbide single-crystal grown on growth surface 8 of seed substrate 3 has a maximum height H of 20 mm or more. Preferably, maximum height H of the silicon carbide single-crystal is 50 mm or more.

In the manufacturing method of the present embodiment, second carbon member 2 is set between seed substrate 3 and silicon carbide source material 7 before the step of growing the silicon carbide single-crystal. In the step of growing the silicon carbide single-crystal, first carbon member 1 is etched at a rate slower than a rate at which second carbon member 2 is etched. Preferably, the distance from growth surface 8 of seed substrate 3 to second carbon member 2 is shorter than the distance from center 11 of growth surface 8 of seed substrate 3 to first carbon member 1. Further, preferably, second carbon member 2 is provided with flow paths 6 for flowing the sublimated silicon carbide gas from the silicon carbide source material 7 side to the seed substrate 3 side. Flow paths 6 are provided at the positions facing growth surface 8 of seed substrate 3.

The following describes function and effect of the present embodiment.

According to the method for manufacturing the silicon carbide single-crystal in the present embodiment, first carbon member 1 provided at the position facing side wall 5 of seed substrate 3 is etched at a rate of 0.1 mm/hour or less. Because first carbon member 1, which forms the side surface portion of crucible 14, is etched at such a low rate, a change in growth condition for the silicon carbide single-crystal is small in crucible 14. Accordingly, the silicon carbide single-crystal can be grown stably.

Further, according to the method for manufacturing the silicon carbide single-crystal in the present embodiment, first carbon member 1 is etched at a rate slower than the rate at which second carbon member 2 is etched. Thus, the etching of first carbon member 1 forming the side surface portion of crucible 14 can be suppressed.

Further, according to the method and device for manufacturing the silicon carbide single-crystal in the present embodiment, the distance from growth surface 8 of seed substrate 3 to second carbon member 2 is shorter than the distance from center 11 of growth surface 8 of seed substrate 3 to first carbon member 1. Accordingly, the etching of second carbon member 2 precedes the etching of first carbon member 1, whereby the etching of the side surface portion of crucible 14, i.e., first carbon member 1 can be suppressed. Further, etching for carbon takes place not only in side wall 5 of seed substrate 3 but also in growth surface 8 of seed substrate 3. Hence, the growth rate of the silicon carbide single-crystal becomes uniform in growth surface 8.

Further, according to the method and device for manufacturing the silicon carbide single-crystal in the present embodiment, second carbon member 2 is provided with flow paths 6 for flowing the sublimated silicon carbide gas from the silicon carbide source material 7 side to the seed substrate 3 side, and flow paths 6 are provided at the positions facing growth surface 8 of seed substrate 3. In this way, the sublimated silicon carbide gas is brought to the seed substrate 3 side via flow paths 6.

### Second Embodiment

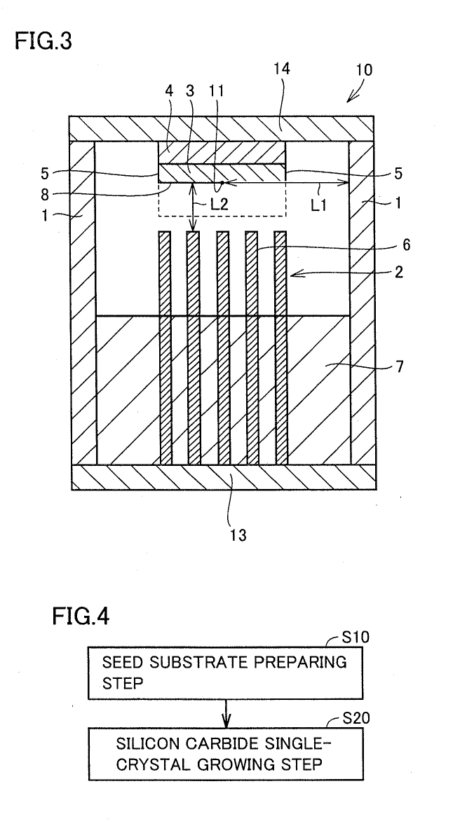

Referring to FIG. 3, the following describes a manufacturing device of a silicon carbide single-crystal in a second embodiment. It should be noted that the manufacturing device of the silicon carbide single-crystal in the second embodiment is different from the manufacturing device of the silicon carbide single-crystal in the first embodiment, in terms of the shape and arrangement of the second carbon members, and has the other configurations substantially the same as those in the manufacturing device according to the first embodiment.

Each of second carbon members 2 according to the second embodiment is formed of a carbon member, and extends from bottom portion 13 of crucible 14 toward growth surface 8 of seed substrate 3. An exemplary carbon member is graphite. A distance L2 from the surface of the highest portion of second carbon member 2 to growth surface 8 of seed substrate 3 is shorter than a distance L1 from center 11 of seed substrate 3 to first carbon member 1, which is a part of crucible 14.

In the present embodiment, second carbon member 2 is in the form of a bar. Second carbon member 2 has one side buried in silicon carbide source material 7, and has the other side not buried in silicon carbide source material 7.

The shape, size, number, arrangement, and the like of second carbon members 2 are not particularly limited. For example, each of second carbon members 2 may have a cross sectional shape of polygon such as a quadrangle or a hexagon, or may have a cross sectional shape such as a circle or an ellipse. Further, one or a plurality of second carbon members 2 may be provided. Further, second carbon members 2 may be arranged in a periodic manner or a symmetrical manner, or may be arranged in a random manner. The arrangement of carbon members 2 may be of three-fold symmetry or six-fold symmetry, for example.

In the present embodiment, the plurality of second carbon members 2 provide flow paths 6 for flowing the sublimated silicon carbide gas from the silicon carbide source material 7 side to the seed substrate 3 side. Flow paths 6 are provided at positions facing growth surface 8 of seed substrate 3.

The following describes function and effect of the present embodiment.

Each of second carbon members 2 of the manufacturing device of the silicon carbide single-crystal in the present embodiment extends from bottom portion 13 of crucible 14 toward growth surface 8 of seed substrate 3 through silicon carbide source material 7. Accordingly, silicon carbide source material 7 can be efficiently heated by second carbon member 2.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide single-crystal having a diameter of more than 100 mm and a maximum height of 20 mm or more using a sublimation method, comprising the steps of:
preparing a seed substrate made of silicon carbide, and a silicon carbide source material; and
growing said silicon carbide single-crystal on a growth surface of said seed substrate by sublimating said silicon carbide source material, a first carbon member provided at a position facing a side wall of said seed substrate being etched at a rate of 0.1 mm/hour or less in the step of growing said silicon carbide single-crystal.

2. The method for manufacturing the silicon carbide single-crystal according to claim 1, wherein in the step of growing said silicon carbide single-crystal, said first carbon member is etched at a rate of 0.05 mm/hour or less.

3. The method for manufacturing the silicon carbide single-crystal according to claim 1, wherein said silicon carbide single-crystal has a maximum height of 50 mm or more.

4. The method for manufacturing the silicon carbide single-crystal according to claim 1, further comprising the step of disposing a second carbon member between said seed substrate and said silicon carbide source material before the step of growing said silicon carbide single-crystal, wherein
in the step of growing said silicon carbide single-crystal, said first carbon member is etched at a rate slower than a rate at which said second carbon member is etched.

5. The method for manufacturing the silicon carbide single-crystal according to claim 4, wherein a distance from said growth surface of said seed substrate to said second carbon member is shorter than a distance from a center of said growth surface of said seed substrate to said first carbon member.

6. The method for manufacturing the silicon carbide single-crystal according to claim 4, wherein
said second carbon member is provided with a flow path for flowing silicon carbide gas, which is sublimated from said silicon carbide source material, from a side of said silicon carbide source material to a side of said seed substrate, and
said flow path is provided at a position facing said growth surface of said seed substrate.

7. A device for manufacturing a silicon carbide single-crystal using a seed substrate having a growth surface on which said silicon carbide single-crystal is to be grown, comprising:
a crucible for containing a silicon carbide source material, said crucible having a side surface portion formed of a first carbon member disposed at a position facing a side wall of said seed substrate; and
a second carbon member disposed between said seed substrate and said silicon carbide source material,
said second carbon member forming a flow path for flowing silicon carbide gas, which is sublimated from said silicon carbide source material, from a side of said silicon carbide source material to a side of said seed substrate,
said flow path being provided at a position facing said growth surface of said seed substrate,
a distance from said growth surface of said seed substrate to said second carbon member being shorter than a distance from a center of said growth surface of said seed substrate to said first carbon member disposed at the position facing said side wall of said seed substrate.
